(19) United States
(12) Patent Application Publication
(10) Pub. No.: US 2020/0028361 A1
(43) Pub. Date: Jan. 23, 2020

(54) POWER SWITCHING DEVICE FOR AN ELECTRICAL POWER DISTRIBUTION SYSTEM, IN PARTICULAR FOR AN AIRCRAFT, WITH METERING OF THE CONSUMED ELECTRICAL POWER

(71) Applicant: ZODIAC AERO ELECTRIC, Montreuil (FR)

(72) Inventor: Stéphane Guenot, Montreuil (FR)

(21) Appl. No.: 16/514,915

(22) Filed: Jul. 17, 2019

(30) Foreign Application Priority Data
Jul. 18, 2018 (FR) 1856636

(51) Int. Cl. H02J 3/14; G01R 21/06; G01R 21/00; B64D 31/14

(52) U.S. Cl. CPC H02J 3/14; G01R 21/06; G01R 21/002; H02J 2003/001; B64D 31/14; B64D 2221/00; G01R 21/003

(57) ABSTRACT

A power switching device for an electrical power distribution system. The power switching device is configured for supplying an electrical load with power, having switching means and means for protecting the loads. The device includes current measurement means and voltage measurement means delivering current and voltage measurement signals to a driver stage of the device. The device includes processing means that are capable of formulating information relating to the electrical power consumed by the loads on the basis of the voltage and current measurement signals.

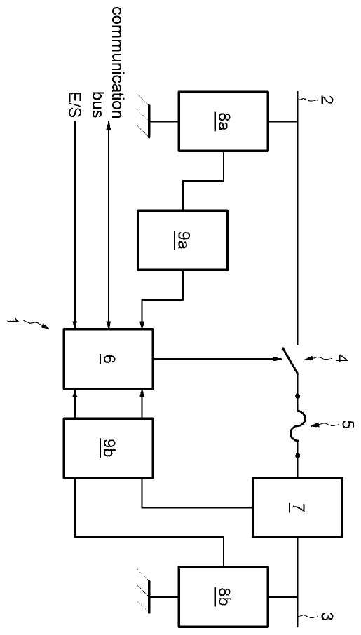

### CROSS-REFERENCE TO RELATED APPLICATIONS

The present application claims priority to French Patent Application No. 1856636, filed on Jul. 18, 2018, the content of which is incorporated herein by reference in its entirety.

### FIELD OF INVENTION

The present invention relates, in general, to power supply systems for an electrical power distribution network, in particular for an aircraft electrical power distribution network.

### BACKGROUND

The electrical power supply system of an aircraft generally has a pyramidal structure and comprises a primary electrical power distribution system and a secondary distribution system.

Power is distributed by means of electronic or electromechanical distribution components, such as solid-state power controllers (SSPCs), and residual-current protection devices of the RCCB (remote-controlled circuit breaker) type.

These distribution components incorporate functions for electrically protecting the cables for supplying the loads with power, which intervene in the event of a fault generating a current that is liable to damage the cables with which they are associated.

Power switching is performed by the switching components, which also provide the loads with protection.

Driver circuit boards perform the function of managing the control and communication logic for the components.

The switching components also provide the driver circuit boards with current and voltage measurements.

The protections put in place are based on criteria of minimum or maximum allowed current or voltage values. A protection function is therefore not triggered if the values of the current and of the voltage that are consumed by the loads, considered individually, meet the minimum or maximum value criteria.

The power distribution components generally transmit the RMS values of the distributed currents to the control members.

However, without additional processing, this information is not enough to make it possible to establish effective management of the distributed power.

Specifically, knowledge of the RMS value of the current alone does not make it possible to appreciate the power values that are consumed by the loads, the way in which the power is consumed and the nature of the harmonics generated on the network.

This problem is increasingly pressing with the development of loads that are becoming ever more active with the incorporation, for example, of power electronics.

### SUMMARY

In light of the above, the object of the invention is to overcome the limitations connected to the switching devices according to the prior art by expanding the functionalities provided by these switching devices.

The subject of the invention is therefore a power switching device for an electrical power distribution system, for supplying at least one electrical load with power, comprising switching means and means for protecting the loads, comprising current measurement means and voltage measurement means delivering current and voltage measurement signals to a driver stage of the device.

This device comprises processing means that are capable of formulating information relating to the electrical power consumed by the loads on the basis of the voltage and current measurement signals.

This information make it possible in particular to ascertain the nature and the value of the electrical power consumed by the loads and thus makes it possible to understand the behaviour of the supplied loads better and thus to manage the network better.

The invention makes it possible in particular to meter the electrical power consumed by the loads and provides information on compliance with standard requirements or on the good state of health of each load, by comparing, for example, the formulated information with information corresponding to a load in a good state of health.

Tracking the variation in the consumed power may, likewise, indicate whether a load is deteriorating and whether maintenance is required.

The invention therefore makes it possible to carry out anticipatory load shedding before the load becomes faulty and the electrical network suffers the effect of such a fault.

Knowledge of the power consumed by the loads may, for example, allow a load consuming too much reactive power to be disconnected.

For example, with regard to the loads on board an aircraft, knowledge of the power consumed in the cabin may allow the elements of the distribution system to be properly sized.

Specifically, the electrical distribution architectures for equipment that may be used by passengers include a large number of power boxes, which are mainly installed in the seats. The amount of power available is thus very high with respect to the amount of power that is actually consumed.

Knowledge of the power that is actually consumed by passengers makes it possible, through data analysis, to size the equipment installed on board aircraft and, consequently, to make relatively substantial weight and consumption savings.

According to another feature of the device according to the invention, it further includes means for formulating the RMS value of the current and of the voltage delivered to the loads.

For example, the processing means include means for calculating the phase shift between the voltage and current.

They may, in this case, include means for calculating the cosine of the angle of said phase shift.

The processing means may further include means for calculating the active power and/or the reactive power consumed by the loads.

According to yet another feature, the processing means includes means for driving the switching means on the basis of the value of the measured voltage.

Other objects, features and advantages will become apparent upon reading the following description, provided solely by way of nonlimiting example, and with reference to the appended drawing, which illustrates the general structure of a power switching device for a power distribution system for an aircraft according to the invention.

### DESCRIPTION OF THE DRAWINGS

The power switching device illustrated in the FIGURE is in particular intended to be incorporated within a primary electrical power distribution system or in a secondary distribution system of an onboard network of an aircraft.

It is intended to provide the power-switching and the protection of the loads and of the cables of the power supply network.

### DETAILED DESCRIPTION

This device, denoted by the general numerical reference 1, is intended to be connected between a power input 2 and a power output 3 of a power line and includes a switching member 4 for distributing electrical power and protecting the loads and/or the power supply cables, and an auxiliary safety member 5, of the fuse type, for example placed between the switching member 4 and the power output 3.

The switching member 4 is driven by a computing and processing unit 6 on the basis of current and voltage measurement signals.

The power switching device is thus supplemented by a current sensor 7, placed for example between the safety member 5 and the power output 3, and voltage sensors 8a and 8b, placed at the power input and at the power output and measuring the voltage conveyed over the power line. The voltage value delivered by the voltage sensors 8a and 8b is advantageously the phase-to-neutral voltage of the power supply line.

The measurement signals from the current and voltage sensors are delivered to conditioning stages 9a and 9b used for conditioning and shaping the signals delivered by the sensors with a view to their processing by the processing unit 6. They perform in particular the sampling of the measurement signals at a frequency that is substantially high with respect to the frequency of the power supply network.

It may additionally be seen that the processing unit 6 communicates with a bus for communicating and transmitting data and is also capable of communicating with a digital input and output E/S.

The computing unit incorporates all of the hardware and software means that are capable of driving the switching member on the basis of the signals from the sensors and for calculating information relating to the electrical power consumed by the loads on the basis, in particular, of the measurements of current and voltage conveyed over the power line.

The computing unit additionally receives the state of the power switch of the switching member 4, namely open, closed, not in use, etc., and information pertaining to the state of the protections put in place by the switching member and the safety member 5, namely active or inactive.

First and foremost, the processing unit 6 ensures that the measured input voltage meets the conditions for the power switch to be able to be closed. To this end, the input voltage is compared with minimum and maximum admissible values.

With regard to the voltage conveyed over the power line, the processing unit 6 acquires the phase-to-neutral voltage value, determines the time of zero crossing of the voltage, for example by interpolation or estimation on the basis of an acquired direct value, and also calculates the RMS value of the voltage.

With regard to the current distributed to the load, the processing unit 6 acquires the value of the line current or that delivered to the load, calculates the RMS value of this value and determines the time of zero crossing of the current.

To avoid introducing overly large measurement errors or making the processing overly complex, the voltage and the current are acquired substantially synchronously.

The processing unit 6 additionally calculates the phase shift between the voltage and the current, by measuring the time difference between the voltage and the current, calculates the value of the cosine of the phase-shift angle Phi between the voltage and the current, and also calculates the value of the sine of this angle.

The active power consumed by the load is calculated by calculating the product:

Vrms×Irms×Cosinus(Phi) (1)

The consumed reactive power is calculated by calculating the product:

Vrms×Irms×Sinus(Phi) (2)

where

Vrms and Irms denote the RMS voltage and the RMS current, respectively.

The power switching device thus formulates, on the basis of the signals delivered by the current and voltage sensors, information relating to the electrical power consumed by the loads on the basis of current and voltage values. These signals were used, in the prior art, for the protection of the loads and power-switching.

The power metering implemented by the power switching device makes it possible to improve the management of the electrical power distribution, by virtue of the metering and of the power management, to track the variation in the loads and to size the elements of the distribution system.

1. A power switching device for an electrical power distribution system, the power switching device being configured for supplying at least one electrical load with power, the power switching device comprising:
switching means;
means for protecting the at least one load;
current measurement means;
voltage measurement means delivering current and voltage measurement signals to a driver stage of the device, and
processing means that are configured for formulating information relating to the electrical power consumed by the at least one load based on the voltage and current measurement signals.

2. The device of claim 1, further comprising means configured for formulating a RMS value of a current and a voltage delivered to the at least one load.

3. The device of claim 1, wherein the processing means include means for calculating a phase shift between the voltage and current.

4. The device of claim 3, comprising means for calculating a cosine of an angle of said phase shift.

5. The device of claim 1, wherein the processing means include means for calculating an active power consumed by the at least one load.

6. The device of claim 1, wherein the processing means include means for calculating a reactive power consumed by the at least one load.

7. The device of claim 1, wherein the processing means include means for driving the switching means based on a value of the measured voltage.
